(19) United States
(12) Patent Application Publication
(10) Pub. No.: US 2025/0133721 A1
(43) Pub. Date: Apr. 24, 2025

(54) MEMORY DEVICE HAVING HEXAGONAL MEMORY CELLS WITH INTEGRATED DIGIT LINES

(71) Applicant: Micron Technology, Inc., Boise, ID (US)

(72) Inventors: Fatma Arzum Simsek-Ege, Boise, ID (US); Efe Sinan Ege, Boise, ID (US); Haitao Liu, Boise, ID (US)

(21) Appl. No.: 18/777,695

(22) Filed: Jul. 19, 2024

Related U.S. Application Data
(60) Provisional application No. 63/544,703, filed on Oct. 18, 2023.

(51) Int. Cl. H10B 12/00; H01L 29/06; H01L 29/423; H01L 29/66; H01L 29/775; H01L 29/786

(52) U.S. Cl. CPC H10B 12/315; H10B 12/0335; H10B 12/05; H10B 12/09; H10B 12/482; H10B 12/488; H10B 12/50; H10D 30/014; H10D 30/43; H10D 30/6735; H10D 30/6757; H10D 62/121

(57) ABSTRACT

A variety of applications can include a memory device having an array of memory cells arranged as hexagonal cells, with each of the memory cells having a gate-all-around (GAA) transistor coupled to a capacitor. An access line can be coupled to gates of a first set of multiple GAA transistors of the memory cells. A digit line can be coupled to a second set of multiple GAA transistors of the memory cells, where the digit line is wrapped on a sidewall of an active area of each GAA transistor of the second set. Additional devices and methods are disclosed.

### PRIORITY APPLICATION

This application claims the benefit of priority to U.S. Provisional Application Ser. No. 63/544,703, filed Oct. 18, 2023, which is incorporated herein by reference in its entirety.

### FIELD OF THE DISCLOSURE

Embodiments of the disclosure relate generally to integrated circuits, and more specifically, to memory devices and formation thereof.

### BACKGROUND

Memory devices are typically provided as internal, semiconductor, integrated circuits (ICs) in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered and includes flash memory, read-only memory (ROM), electrically erasable programmable ROM (EEPROM), erasable programmable ROM (EPROM), resistance-variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the design and fabrication of components of the electronic devices such as, but not limited to, memory devices in an IC for the electronic devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates a top view of a representation of an open digit line architecture for the case of shared access lines for one or more arrays of memory cells, where each memory cell includes a gate-all-around transistor coupled to a capacitor, in accordance with various embodiments.

FIG. 2 illustrates a structure having an arrangement of memory cells, where each memory cell has an access transistor and a capacitor, where the access transistor is a gate-all-around transistor having an active area integrated with a digit line, in accordance with various embodiments.

FIGS. 3-37 illustrate features associated with an example process flow of forming a memory device having the arrangement of memory cells of the structure of FIG. 2, in accordance with various embodiments.

FIG. 38 illustrates an example architecture in which the structure of FIG. 34 or similar structure can be located, in accordance with various embodiments.

FIG. 39 is a flow diagram of features of an example method of forming a memory device, in accordance with various embodiments.

FIG. 40 is a flow diagram of features of an example method of forming a memory device, in accordance with various embodiments.

FIG. 41 is a schematic of an electrical arrangement of components of an example dynamic random-access memory device that can include an architecture having hexagonal memory cells with gate-all-around transistors, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above and can be in a direction from the horizontal or to the horizontal. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

In various embodiments, a memory device can be structured with an array of memory cells arranged as hexagonal cells, where each of the memory cells has a gate-all-around (GAA) transistor coupled to a capacitor. A hexagonal memory cell is a memory cell that is surrounded by six other memory cells such that these other memory cells are at vertices of a hexagonal structure formed by connecting the centers of adjacent memory cells of these other memory cells. A GAA transistor is a transistor structured with the gate of the transistor coupled with the channel structure of the transistor on all sides of the channel structure. The GAA transistor can be structured as a thin film transistor (TFT). The GAA transistor can be structured in a pillar arrangement containing active areas (source and drain) and the channel structure about which the gate is structured around. The pillar structure of the GAA transistor can be structured as a semiconductor nanowire. Nanowires are nanostructures having a diameter on the order of nanometers.

A GAA nanowire transistor as an access device to a capacitor in memory cells of a DRAM can provide enhanced I_{ON} capability and flexible adjustment of transistor threshold voltage (V_{T}). I_{ON} is the on-state current of the transistor, where the current, I_{OFF}, is the off-state current of the transistor. The ratio, I_{ON}/I_{OFF}, is a figure of merit for high performance and low-leakage power for the transistor. High performance is associated with more I_{ON} and low-leakage power is associated with less I_{OFF}.

The memory device, having one or more arrays of hexagonal memory cells of GAA transistors, can be implemented with control logic and sensing circuitry in a number of different architectures. The control logic and sensing circuitry can be located in a periphery region adjacent to an array of hexagonal memory cells on a wafer that is an IC chip. Another compatible architecture includes the control logic and sensing circuitry located under the one or more memory arrays in a circuit under array (CuA) architecture. The control logic and sensing circuitry can be arranged for sensing the programmed data states of memory cells of one or more memory arrays of the memory device, and can enhance reduction of die size or increase utilization of space in a die or combination of dies. CuA refers generally to circuitry located in a memory die under a memory array of the memory die. With the control logic and sensing circuitry fabricated under the memory array using semiconductor processing that can include CMOS (Complementary Metal Oxide Semiconductor) processing technology, CoA can also be referred to as CMOS under array.

Another compatible architecture can include control logic and sensing circuitry located above the memory arrays in a circuit over array (CoA) architecture. The control logic and sensing circuitry can be arranged for sensing the programmed data states of memory cells of one or more memory arrays of the memory device, and can enhance reduction of die size or increase utilization of space in a die or combination of dies. CoA refers generally to circuitry located in a memory die over one or more memory arrays of the memory die. With the control logic and sensing circuitry fabricated over the one or more memory arrays using semiconductor processing that can include CMOS, CoA can also be referred to as CMOS over array. The CuA architecture and the CoA architecture can be implemented with a wafer-to-wafer architecture, where the control logic and sensing circuitry is formed on one wafer and the one or more memory arrays are formed on another wafer, with the two wafers combined. Wafer-to-wafer interconnect architectures can include a wafer-on-wafer architecture. Wafer-to-wafer bonding of back-to-back wafers with a CoA architecture can provide for the movement of a capacitor module for data storage in a DRAM to the bottom of the stack of wafers. This arrangement can reduce interconnect congestion between stacked wafers.

The memory device can include a set of access lines (WLs), where each WL of the set of WLs can be coupled to gates of a first set of multiple GAA transistors of the memory cells of a memory array. With a two-sided WL to GAA transistor of a memory cell, control of the WL resistance-capacitance (RC) of directly adjacent WLs can be attained. Each WL can be formed with formation of corresponding gates of GAA transistors in a replacement gate process, which can provide enhanced gate control. The memory device can include a set of digit lines (BLs), where each BL of the set of BLs can be coupled to a second set of multiple GAA transistors of the memory cells. Each BL can be wrapped on a sidewall of an active area of each GAA transistor of the second set. The BLs can be damascene digits. In a damascene process, a dielectric is first formed on a structure and patterned, followed by metal formation filling the patterned dielectric. The metal formation can be realized by a process appropriate for the metal being forming, such as an appropriate metal deposition. Damascene digits can provide for enhanced digit resistance. The BLs can be placed in the memory device angled at 90° relative to the WLs, where the BLs are vertically separated from the WLs.

The memory device can have a 4F² memory array configuration. Memory cell sizes are measured using an nF² formula where ‘n’ is a constant derived from the cell design and ‘F’ is the feature size of the process technology. For the same feature size, as the cell size becomes smaller, memory capacity increases. In a 4F² memory cell, the WL pitch and the BL pitch equal 2F.

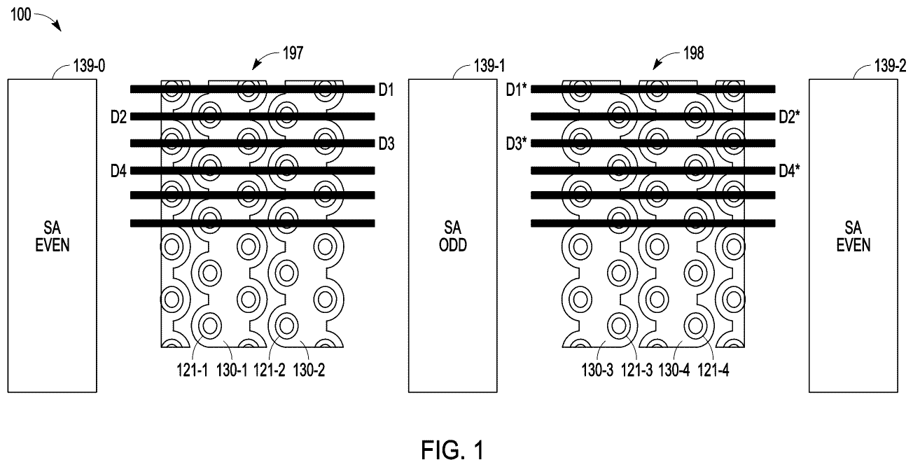

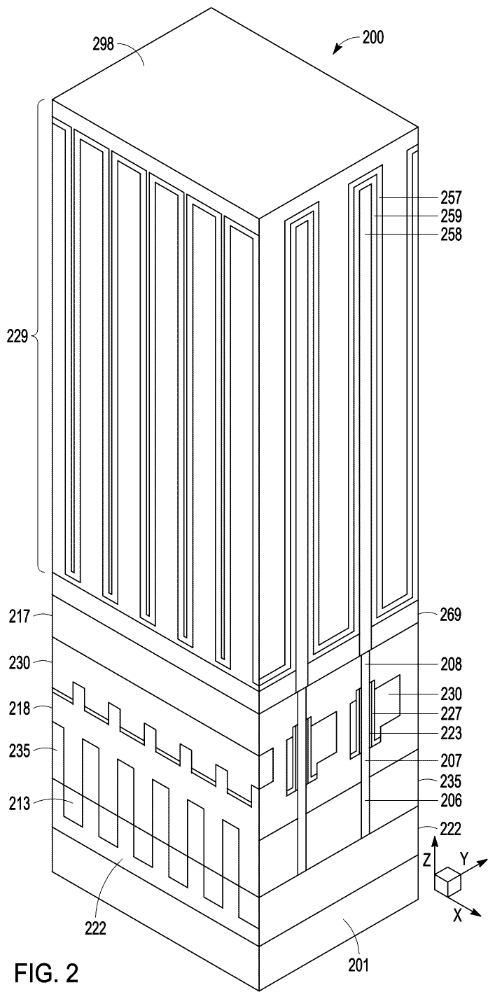

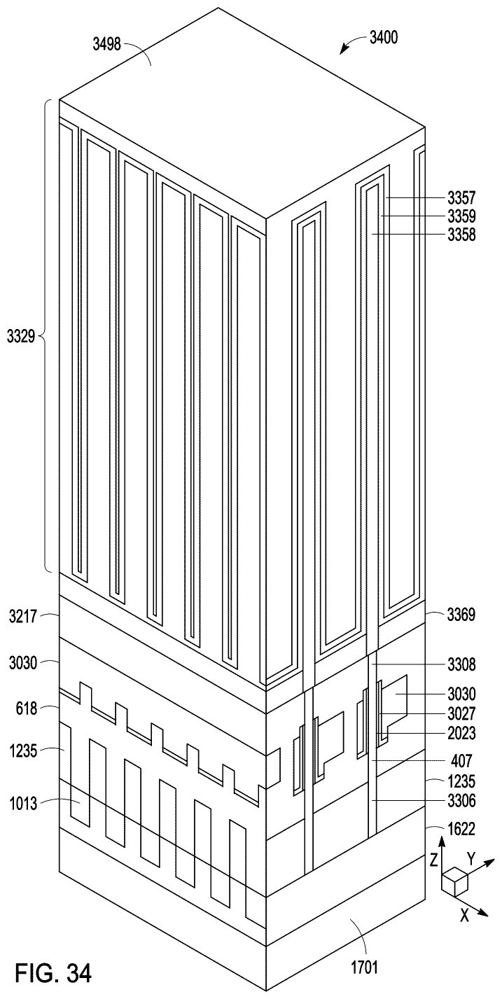

FIG. 1 shows a representation 100 of an open BL architecture for the case of shared WLs for one or more arrays of memory cells, where each memory cell includes a GAA transistor coupled to a capacitor. One of similar multiple features in FIG. 1 and in subsequent figures may be labelled without labeling all similar features, for ease of presentation. The BLs are located on a different physical level of the memory device from the WLs. In an open BL architecture, the BLs are divided into multiple segments and differential sense amplifiers (SAs) are placed between BL segments, where BLs are routed as pairs to a SA from adjacent mats. A mat, which can also be referred as a patch, is a structure for a sub-array, which can be one array of multiple arrays, of memory cells of a larger memory array of a memory device such as the example structure 200 of FIG. 2 and example structure 3400 of FIG. 34. An open BL architecture can also be referred to as an open SA architecture.

The open BL architecture of representation 100 can include SA 139-0, 139-1, and 139-2 in different portions of the memory device structure. BLs D1, D2, D3, and D4 are in region 197, which includes multiple WLs, with each WL shared by multiple memory cells. For example, region 197 can include WLs, 130-1 and 130-2, separated from each other by a dielectric region, where WL 130-1 can be coupled to multiple memory cells 121-1 and WL 130-2 can be coupled to multiple memory cells 121-2. WL 130-1 can be integrated with a gate of the GAA transistor of each memory cell 121-1 and WL 130-2 can be integrated with a gate of the GAA transistor of each memory cell 121-2. BLs D1*, D2*, D3*, and D4* are in region 198, which includes multiple WLs, with each WL shared by multiple memory cells. For example, region 198 can include two WLs, 130-3 and 130-4, separated from each other by a dielectric region, where WL 130-3 can be coupled to multiple memory cells 121-3 and WL 130-4 can be coupled to multiple memory cells 121-4. WL 130-3 can be integrated with a gate of the GAA transistor of each memory cell 121-3 and WL 130-4 can be integrated with a gate of the GAA transistor of each memory cell 121-4.

BLs D1, D2, D3, and D4 can be located between SA 139-0, which can be referred to as an even SA, and SA 139-1, which can be referred to as an odd SA. BLs D1*, D2*, D3*, and D4* can be located between odd SA 139-1 and SA 139-2, which can be referred to as an even SA. Regions 197 and 198 can be formed as individual mats. BLs D1 and D1*, BLs D2 and D2*, BLs D3 and D3*, and BLs D4 and D4* can be arranged as pairs to SA 139-1, with BLs D1, D2, D3, and D4 in region 197 adjacent SA 139-1 and BLs D1*, D2*, D3*, and D4*in region 198 adjacent SA 139-1. Regions 197 and 198 can be formed in individual subtractive processes. A substrative process includes removing material from a solid block of starting material. The GAA transistors and capacitors of structures associated with FIGS. 2 and 34 can be implemented as multiple mats in an open BL architecture.

FIG. 2 illustrates a structure 200 having an arrangement of memory cells, where each memory cell has an access transistor and a capacitor, where the access transistor is a GAA transistor having an active area integrated with a BL. The memory cells are arranged on a wafer, which can be referred to as an array wafer 201, since the memory cells are structured at a level above wafer 201. A bonding dielectric 222 is positioned on array wafer 201, where the bonding dielectric was structured to bond to array wafer 201 during the formation of the memory cells. Within bonding dielectric 222 is a hard mask 213 that is residue from construction of structure 200. A hard mask is a material that can be used as an etch mask in an etch process, where the material is different from a polymer or other relatively soft material such as relatively soft resist materials. A hard mask is typically a high-density material used in the etch process to protect certain areas of a structure being processed from the etching chemicals being used in the etch process. A dielectric 218 is located on bonding dielectric 222 and on hard mask 213. BLs 235 are positioned in dielectric 218, on bonding dielectric 222 and between lines of hard mask 213 at a level above hard mask 213, which provided the pattern for BLs 235 in fabrication.

Semiconductor pillars 207 extend from about a level at the top of hard masks 213. Semiconductor pillars 207 can be realized as nanowires. Each semiconductor pillar 207 includes a channel between two source/drain regions. For each semiconductor pillar 207, a gate dielectric 223 is positioned around the channel provided by semiconductor pillar 207. A gate 227 is positioned around each gate dielectric 223, coupling gate 227 to semiconductor pillar 207, and semiconductor pillar with an WL 230 contacting gate 227. Gate 227 and WL 230 can be structured in a format with WL 230 integrated with multiple gates 227, as shown in the x-direction of FIG. 2. The two source/drain regions of each semiconductor pillar 207 are active areas. Each active area can include a contact junction. For each semiconductor pillar 207, the channel is coupled to a capacitor by active area 208 having a cell contact junction and is coupled to a BL 235 by an active area 206 having a digit contact junction (a digit contact can be referred to as a bit contact or bitcon). The center of BL 235 can be structured to be aligned with the center of the active area 206. Each BL 235 can be wrapped on a sidewall of active area 206, which provides the BL integrated with the memory cell. Active area 206 and BL 235 can be structured in a format with BL 235 integrated with active areas 206, as shown in the y-direction of FIG. 2. Bitcon junction areas can be configured as shields to reduce the capacitance between the BLs.

A dielectric 217 is above gates 227 and WLs 230, with a dielectric 269 is on dielectric 217. Dielectrics 217 and 269 result from processing structure 200 and provide electric isolation to conductive components in structure 200. Above dielectric 269 are a set of capacitors 229. Each capacitor 229 includes a capacitor dielectric 259 between two electrodes 257 and 258. Electrode 258 can be referred to as a bottom electrode that is coupled to active area 208 of semiconductor pillar 207, while electrode 257 is a top electrode that can be coupled to a reference node. Capacitor dielectric can be, but is not limited to, a high-k dielectric. A high-k dielectric is a dielectric having a dielectric constant greater than the dielectric constant of silicon dioxide. Structure 200 can include a dielectric region 298 or connecting wafer on the set of capacitors 229.

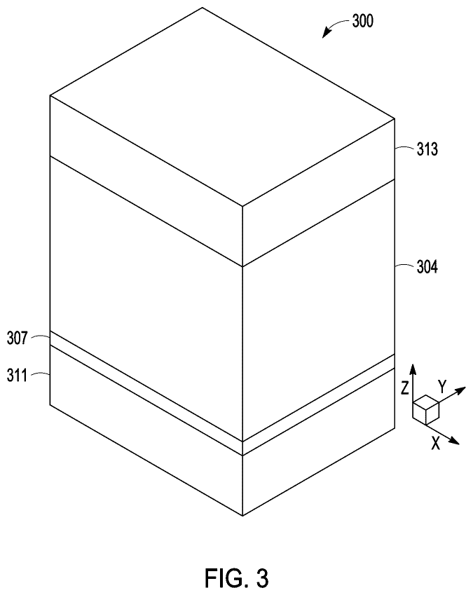

FIGS. 3-37 illustrate features associated with an embodiment of an example process flow of forming a memory device having the arrangement of memory cells of structure 200 of FIG. 2. The memory cells can be arranged with a 4F² architecture. For the procedures discussed herein, the selection of processing materials can depend on the materials selected to form various components of and contacts to components of the memory device. The processing materials can be selected to allow removal of one or more materials, while retaining one or more other materials. In addition, deposition techniques can be used that are typical for the material being formed, the dimensions of the material being formed, and the architecture in which the material is being formed.

FIG. 3 shows a structure 300 after a block of material has been formed on a substrate 311. The block can be semiconductor material. For example, the block can be formed with a layer 307 of silicon germanium (SiGe) on substrate 311, where substrate 311 can be a silicon substrate. The SiGe can be 15% SiGe that can be formed by an appropriate deposition process. Materials other than SiGe can be used. The thickness of the SiGe from substrate 311 can be, but is not limited to, a range between approximately ten to twenty nanometers. Formation of the block of material can include a layer 304 of epitaxial Si formed on the SiGe. Materials other than epitaxial Si can be used. The thickness of the epitaxial Si on the SiGe can be, but is not limited to, a range between approximately 150 nm and 300 nm. Formation of epitaxial Si can be followed by formation of a hard mask 313 on the epitaxial Si.

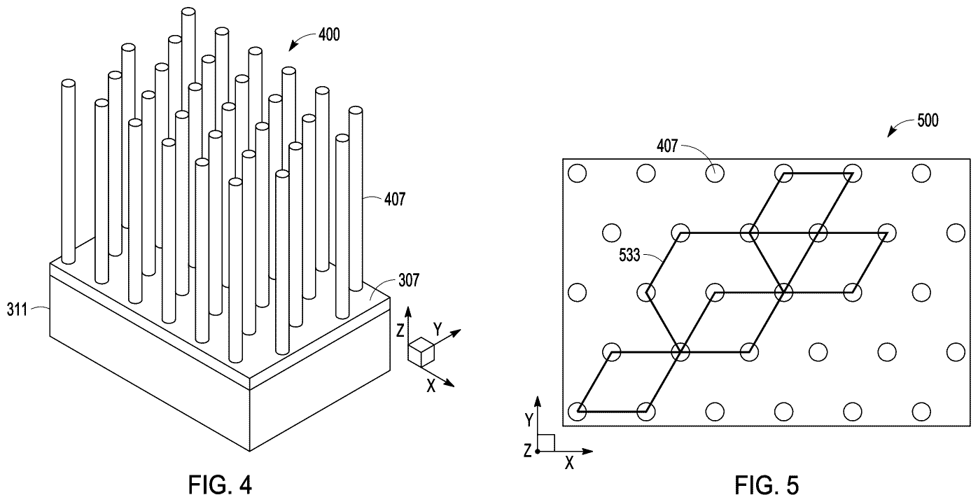

FIG. 4 shows a structure 400 after processing structure 300 of FIG. 3. Channels for GAA transistors have been patterned and formed as pillars 407 from layer 304, with the removal of portions of layer 304 that leaves layer 307 or portions of layer 307. Alternatively, portions of layer 304 of structure 300 can remain with layer 307 in a base to pillars 407 from the processing of forming pillars 407. With layer 304 of structure 300 being epitaxial Si, pillars 407 are pillars of epitaxial Si. Photolithography can be used in the patterning and forming of pillars 407 using deep ultraviolet radiation (DUV) or extreme ultraviolet radiation (EUV). Pillars 407 can be formed having, but are not limited to, channel diameters in the range of approximately 6 nm to 20 nm. The channels can be formed for the GAA access devices having diameters in a range of approximately 20 nm to 50 nm.

FIG. 5 shows a representation 500 of a top view of structure 400 of FIG. 4. Representation 500 illustrates that pillars 407 are arranged as cells with nearest neighbors forming a hexagon 533. Unit repeating cell of pillars 407 is a parallelogram to form a 4F² architecture of memory cells. The hexagonal cells of a 4F² architecture can be formed as smaller cells than square cells of a 4F² architecture.

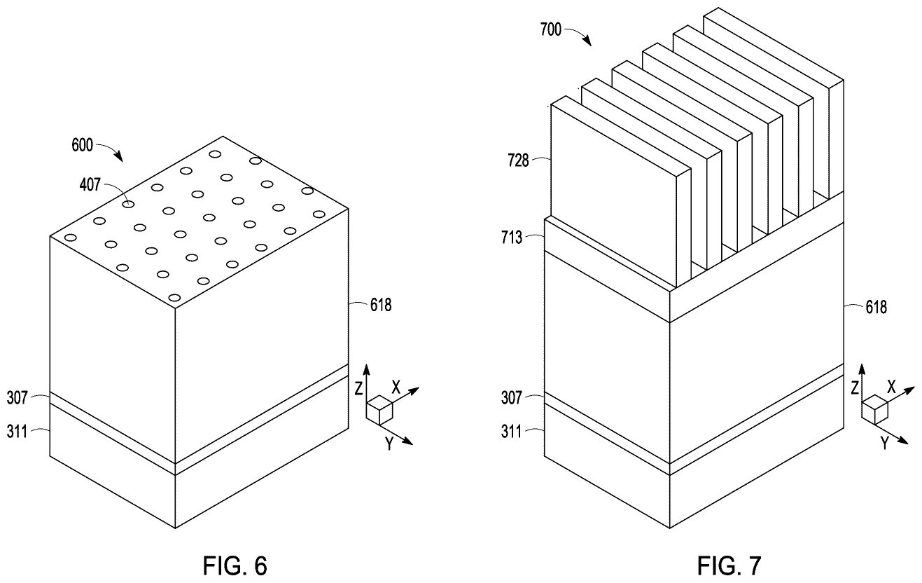

FIG. 6 shows a structure 600 after processing structure 400 of FIG. 4. A dielectric 618 has been formed on layer 307 filling the spaces between pillars 407. Dielectric 618 and pillars 407 have been subjected to a chemical mechanical polishing (CMP) process, leaving the top surfaces of pillars 407 exposed in dielectric 618. Dielectric 618 can be formed by a deposition process suitable for the material of dielectric 618. Dielectric 618 can be an oxide such as, but not limited to, silicon oxide.

FIG. 7 shows a structure 700 after processing structure 600 of FIG. 6. A hard mask 713 has been formed on the top surface of structure 600 and an underlayer 728 for formation of BLs has been formed and patterned on hard mask 713. An underlayer is a carbon-based hard mask placed under photoresist. The formed pattern provides a pattern for a damascene structure for forming BLs. Hard mask 713 and underlayer 728 can be formed by deposition processes suitable for the materials of this portion of the process flow.

FIG. 8 shows a structure 800 after processing structure 700 of FIG. 7. Hard mask 713 has been patterned and portions of dielectric 618 have been removed using underlayer 728, with the removal of underlayer 728. Removal of portions of dielectric 618 has exposed sidewalls of pillars 407. The exposed sidewalls of pillars 407 are processed as active areas for GAA transistors to be formed, where the exposed sidewalls are implanted to form junctions for bitcons to capacitors to be formed in the process flow for forming a memory device having the arrangement of memory cells of structure 200 of FIG. 2. After the implant process, the structure can be subjected to an implant clean process.

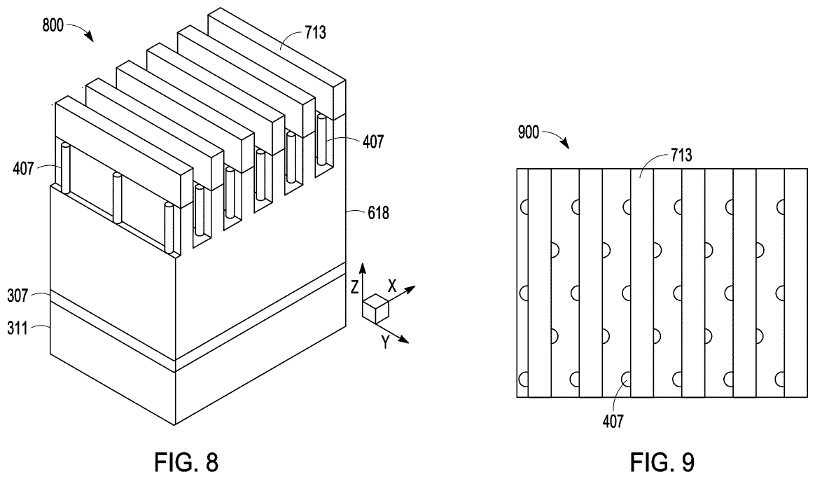

FIG. 9 shows a representation 900 of a top view of structure 800 of FIG. 8. The top view shows the pattern of hard mask 713 having spaces between lines of material of hard mask 713. The spaces are also spaces between pillars 407 under the lines of hard mask 713, where each material line of hard mask 713 partially covers multiple pillars 407.

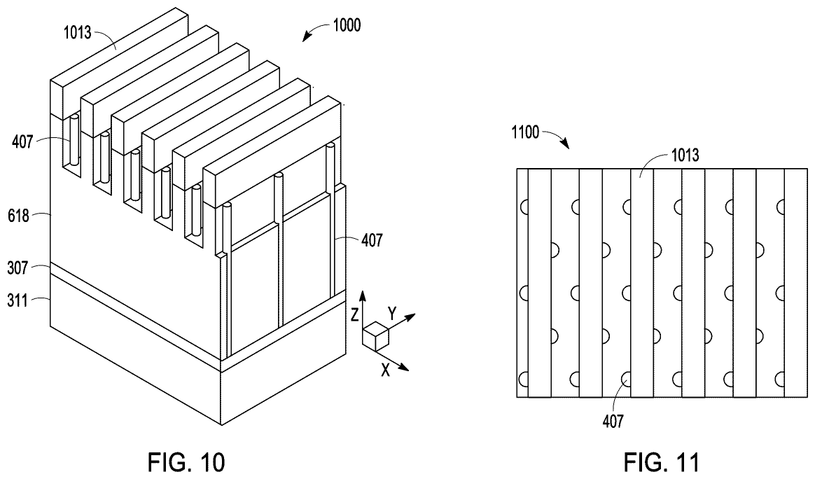

FIG. 10 shows a structure 1000 after possible further processing of structure 800 of FIG. 8. One of the cross-sectional views of structure 1000 illustrates pillars 407 extending down through dielectric 618 to layer 307. The material lines can be further shaped, such as further narrowing, to form dielectric 1013 or can maintain the material and shape of the lines of hard mask 713.

FIG. 11 shows a representation 1100 of a top view of structure 1000 of FIG. 10. The top view shows dielectric 1013 having spaces between lines of dielectric 1013. The spaces are also spaces between pillars 407 under the lines of dielectric 1013, where each material line of dielectric 1013 partially covers multiple pillars 407.

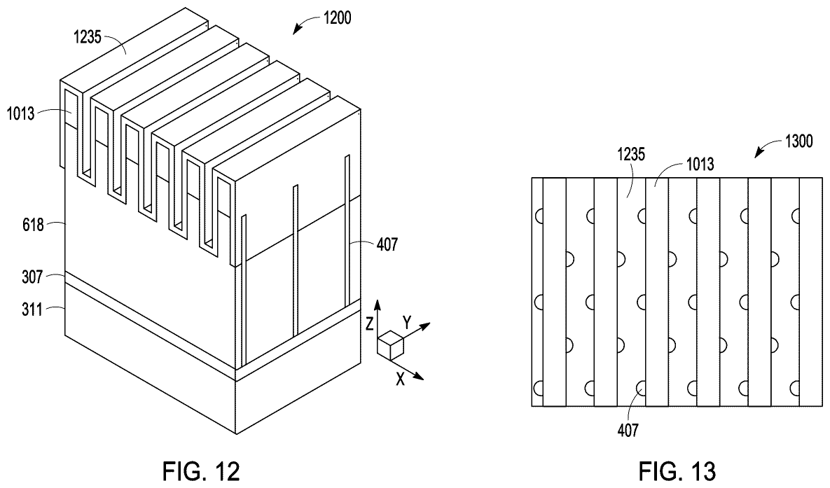

FIG. 12 shows a structure 1200 after processing structure 1000 of FIG. 10. Metal 1235 has been formed on dielectric 1013 and in spaces, shown in FIG. 11, between material lines of dielectric 1013 on the exposed surfaces of structure 1000. Metal 1235 is being formed for BLs in the fabrication of the current process flow. Other conductive material can be used for metal 1235, with properties similar to a conductive metal. Formation of metal 1235 at the relevant locations can be made by a deposition process suitable for the metal being formed on the exposed surfaces of structure 1000. Metal 1235 can be formed at spacing in the range of appropriately 7 nm to 12 nm.

FIG. 13 shows a representation 1300 of a top view of structure 1200 of FIG. 12. In this view, metal 1235 formed on top surfaces of dielectric 1013 are not shown to illustrate metal 1235 formed in the spaces between lines of dielectric 1013 and wrapping pillars 407. Two active areas of pillars 407 are on the left and right sides of each of the lines of dielectric 1013.

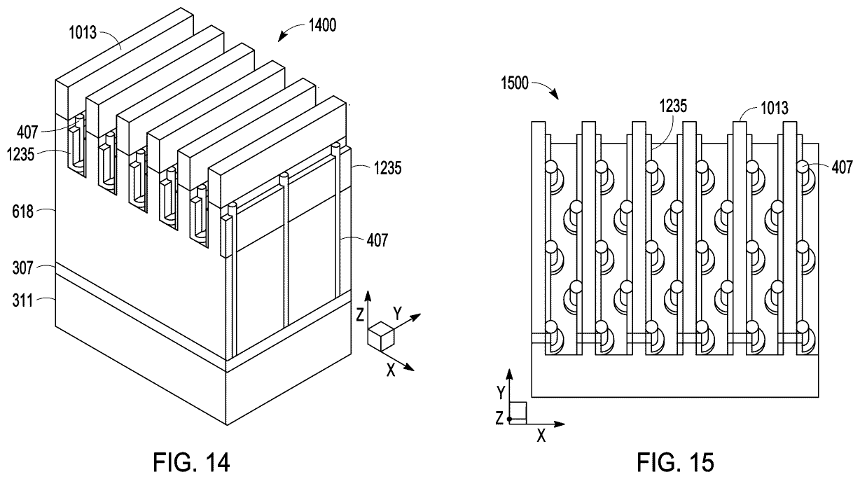

FIG. 14 shows a structure 1400 after processing structure 1200 of FIG. 12. Metal 1235 has been etched, punching through to form isolation trenches. FIG. 15 shows a representation 1500 of a top view of structure 1400 of FIG. 14. Lines of metal 1235 are on two sides under lines of dielectric 1013. FIG. 15 shows the isolation provided by the post metal punch, where metal 1235 is on the two sides of the isolation trench. There can be a smallest metal-to-metal space such as, but not limited to, approximately 5 nm. As shown, metal 1235 wraps pillars 407.

FIG. 16 shows a structure 1600 after processing structure 1400 of FIG. 14. A bonding dielectric 1622 has been formed on the exposed surfaces of structure 1400. Bonding dielectric 1622 covers dielectric 1013 and metal 1235. Bonding dielectric 1622 has been buffed, subjected to a CMP process, and cleaned. Formation of bonding dielectric 1622 can be conducted using a deposition process appropriate for the material selected for bonding dielectric 1622. Material for bonding dielectric 1622 can be, but is not limited to, tetraethoxysilane (TEOS), silicon carbon nitride (SiCN), material for High Aspect Ratio Process (HARP), or combinations of similar materials.

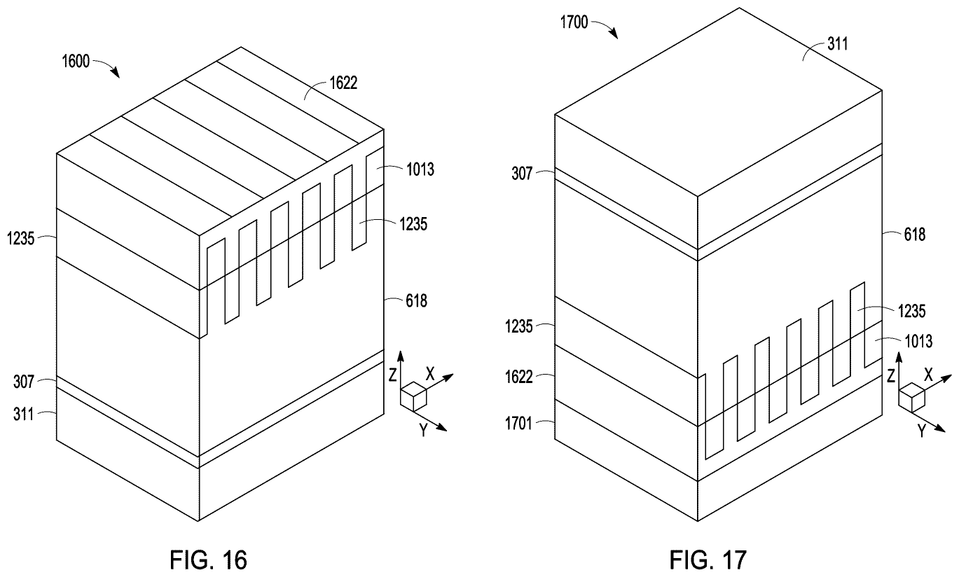

FIG. 17 shows a structure 1700 after processing structure 1600 of FIG. 16. Bonding dielectric 1622 has been bonded to a carrier wafer 1701 and the bonded structure is flipped, placing substrate 311 as the top of structure 1700. Carrier wafer 1701 can be an inexpensive wafer or a glass carrier with an oxide deposited surface. The bonding can be conducted through fusion bonding.

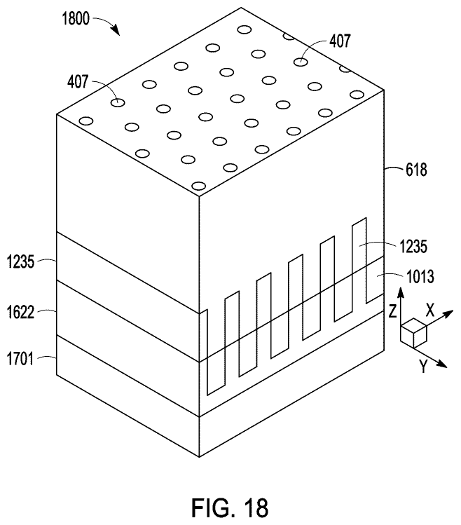

FIG. 18 shows a structure 1800 after processing structure 1700 of FIG. 17. Structure 1700 has been subjected to a CMP procedure that exposes tops of pillars 407 that are being used for channels of GAA transistors being formed in the process flow. These tops of pillars 407 will provide junctions of cell contacts to capacitors. Substrate 311 and layer 307 have been removed.

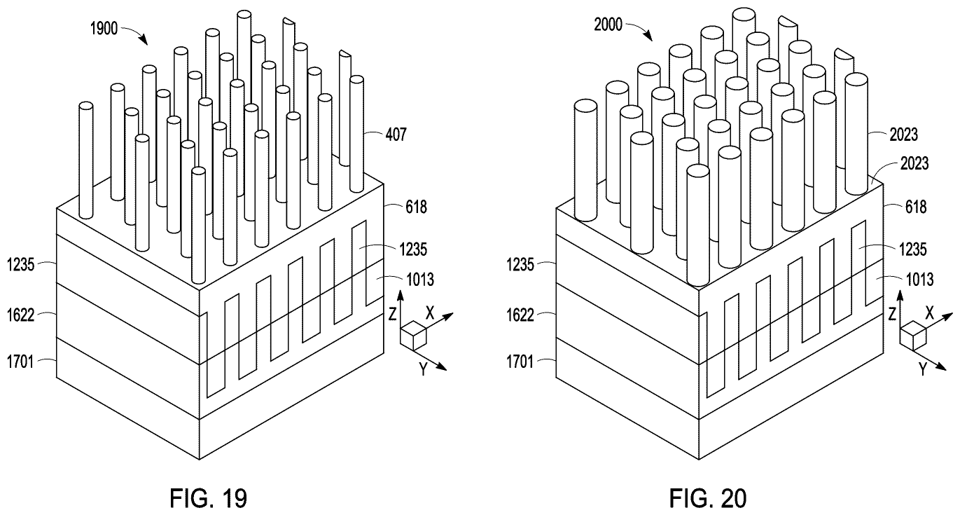

FIG. 19 shows a structure 1900 after processing structure 1800 of FIG. 18. Portions of dielectric 618 have been selectively removed to a selected level of dielectric 618, exposing pillars 407. For dielectric 618 being an oxide and pillars 407 being silicon, oxide of dielectric 618 is recessed selective to a Si surface. A selective wet etch can be used for the purpose of the recess of dielectric 618 to a specified level. The selective wet etch can be a time-controlled etch.

FIG. 20 shows a structure 2000 after processing structure 1900 of FIG. 19. Dielectric material 2023 has been formed on the exposed surfaces of structure 1900. Dielectric material 2023 covers the exposed portions of pillars 407 and will provide a gate dielectric for GAA transistors being formed about pillars 407. Dielectric material 2023 can be, but is not limited to, gate oxide material. Dielectric material 2023 can be formed by a deposition procedure that is suitable for the selected material for dielectric material 2023. Alternatively, dielectric material 2023 can be formed by in-situ steam generation (ISSG), where an ISSG procedure includes generation of steam in close proximity to a wafer surface, providing a wet oxidation.

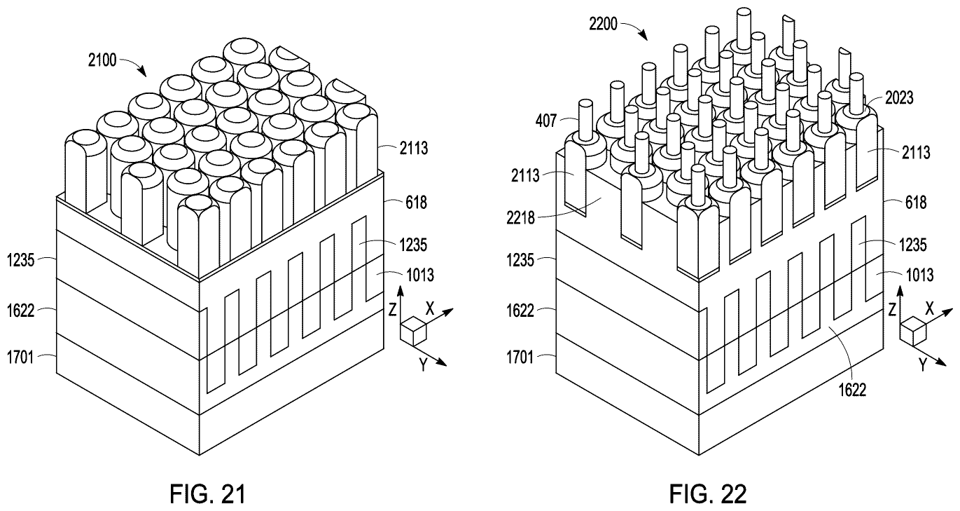

FIG. 21 shows a structure 2100 after processing structure 2000 of FIG. 20. A liner 2113 has been formed on the exposed structure 2000. Formation of liner 2113 can be conducted using a deposition procedure appropriate for the material of liner 2113. Liner 2113 can be, but is not limited to, a nitride liner. Liner 2113 is form as a sacrificial liner in the process flow.

FIG. 22 shows a structure 2200 after processing structure 2100 of FIG. 21. A dielectric 2218 has been formed over the exposed surfaces of structure 2100, filing spaces between liners 2113, and has been subjected to a CMP procedure. Dielectric 2218 can be, but is not limited to, an oxide. The resulting structure from the CMP procedure has been selectively etched back, exposing pillars 407. For dielectric 2218 being an oxide and the pillars 407 being Si, the selective etch back can be a dry etch back selective to Si, exposing portions of pillars 407 designed for a junction of cell contacts to be made to capacitors.

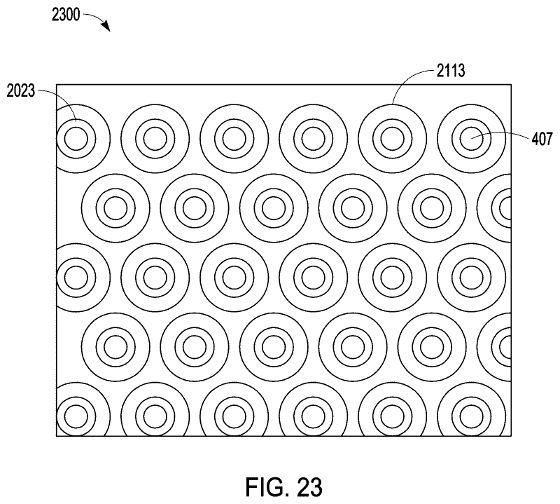

FIG. 23 shows a representation 2300 of a top view of structure 2200 of FIG. 22. FIG. 23 shows an array of cells being formed. Each cell represented includes a center pillar 407, providing a channel, surrounded by dielectric material 2023, provided as gate material, where dielectric material 2023 is surrounded by liner 2113.

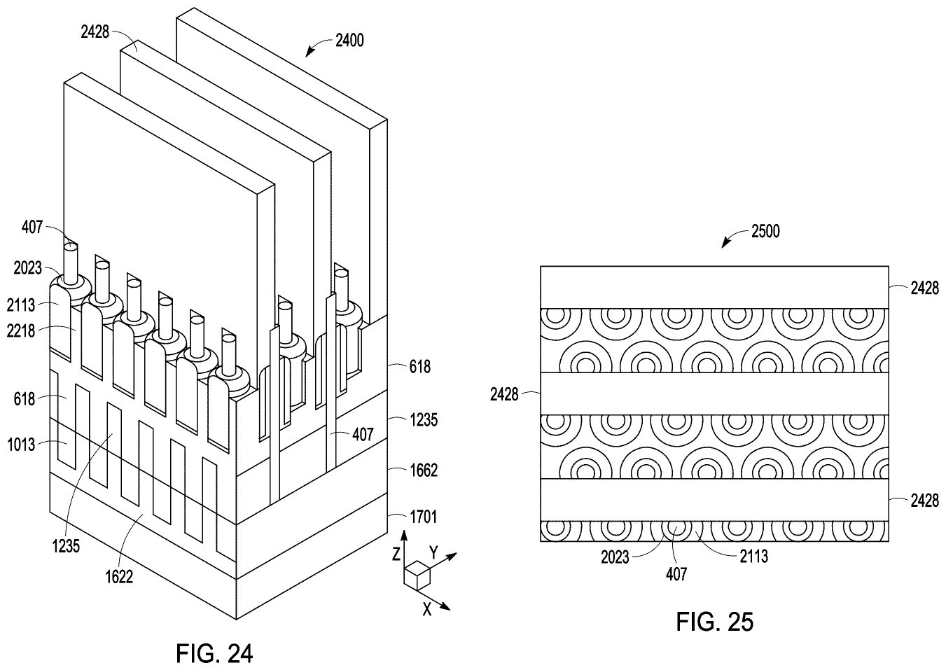

FIG. 24 shows a structure 2400 after processing structure 2200 of FIG. 23. A photolithographic procedure has been conducted for preparing WLs. A carbon-based hard mask 2428 has been applied to the surface of structure 2200 and has been selectively removed to a top surface of dielectric 2218. A dry etch can be used to form the pattern of carbon-based hard mask 2428 shown in FIG. 24.

FIG. 25 shows a representation 2500 of a top view of structure 2400 of FIG. 24. FIG. 25 shows the pattern of carbon-based hard mask 2428 relative to cells having center pillar 407 surrounded by dielectric material 2023 that is surrounded by liner 2113.

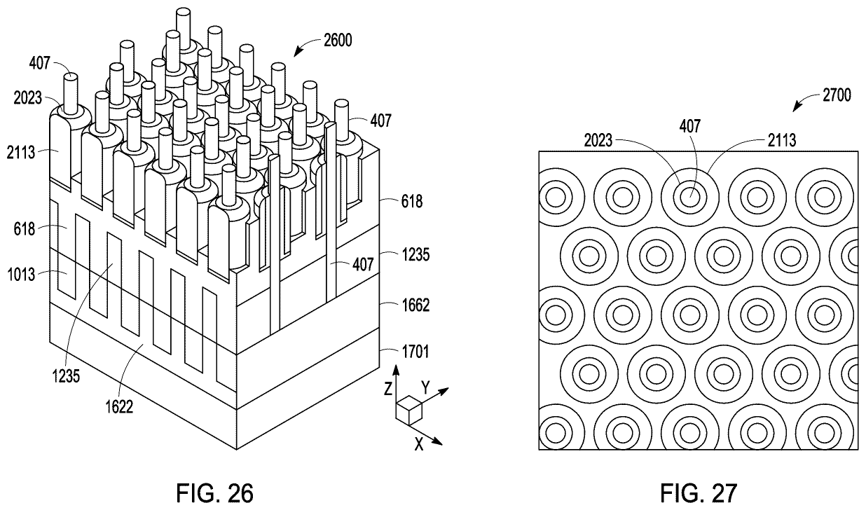

FIG. 26 shows a structure 2600 after processing structure 2400 of FIG. 24. Carbon-based hard mask 2428 has been stripped. FIG. 27 shows a representation 2700 of a top view of structure 2600 of FIG. 26. FIG. 27 again illustrates the array of cells being formed. Each cell represented includes center pillar 407 surrounded by dielectric material 2023 that is surrounded by liner 2113.

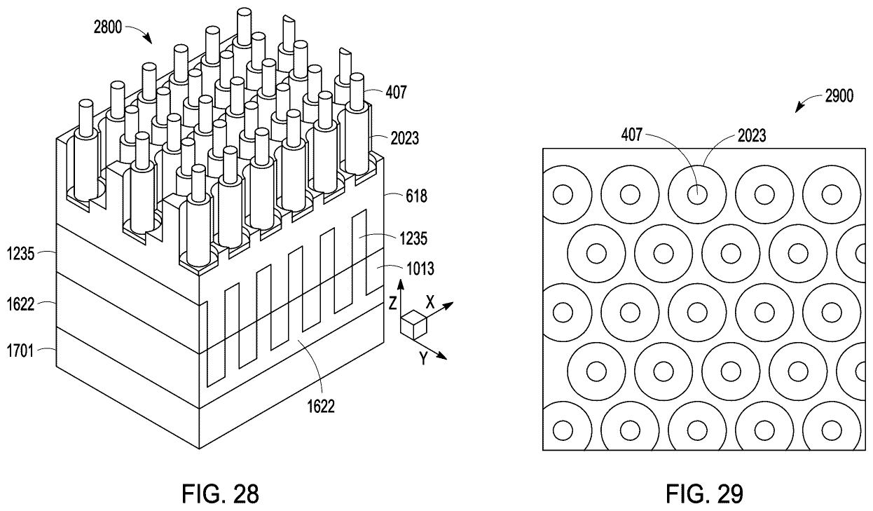

FIG. 28 shows a structure 2800 after processing structure 2600 of FIG. 26. Liner 2113, which was a sacrificial liner, has been removed. A wet etch can be used to remove liner 2113. With liner 2113 being a nitride liner and pillars 407 being silicon, the nitride can be removed with a wet etch selective to oxide. For example, hot phosphide can be used in the wet etch.

FIG. 29 shows a representation 2900 of a top view of structure 2800 of FIG. 28. FIG. 29 illustrates the array of cells being formed. Each cell represented includes center pillar 407 surrounded by dielectric material 2023. Liner 2113 is no longer part of the cells.

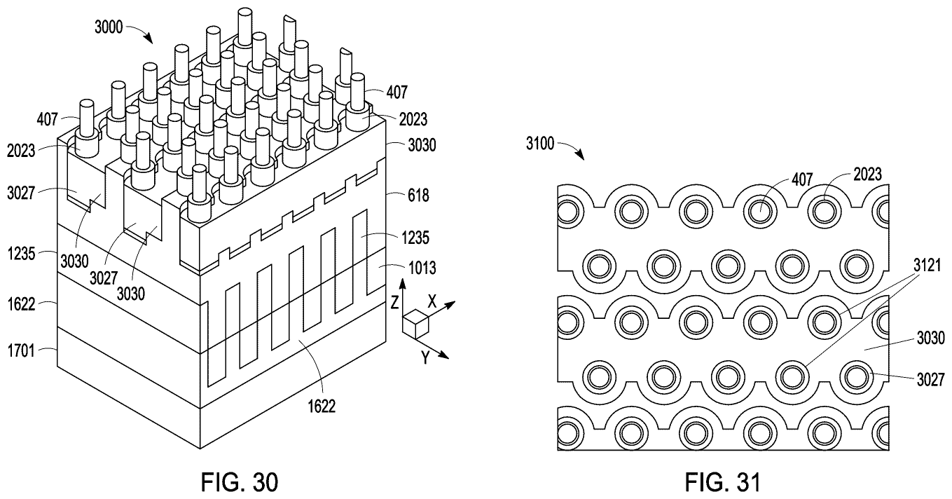

FIG. 30 shows a structure 3000 after processing structure 2800 of FIG. 28. Conductive material 3027 has been formed for gates and conductive material 3030 has been formed for WLs. Conductive material 3027 and conductive material 3030 can be formed by an appropriate deposition technique, which can be chemical vapor deposition (CVD) or atomic layer deposition (ALD). Conductive material 3027 can be formed as metal deposited to form gates of GAA transistors and conductive material 3030 can be formed as metal deposited to form the WLs. The formed conductive material 3030 has been recessed back as shown in FIG. 30.

FIG. 31 shows a representation 3100 of a top view of structure 3000 of FIG. 30. Conductive material 3030 for WLs is wrapped around conductive material 3027 for gates of GAA transistors that are being coupled to conductive material 3030, providing for a set of memory cells coupled to an WL. Conductive material 3027 for gates of the GAA transistors can be referred to as gates 3027. The center of conductive material 3030 for one access line can be structured at the middle between two adjacent GAA transistors 3121 that are access devices for two memory cells, where each memory cell can store a bit.

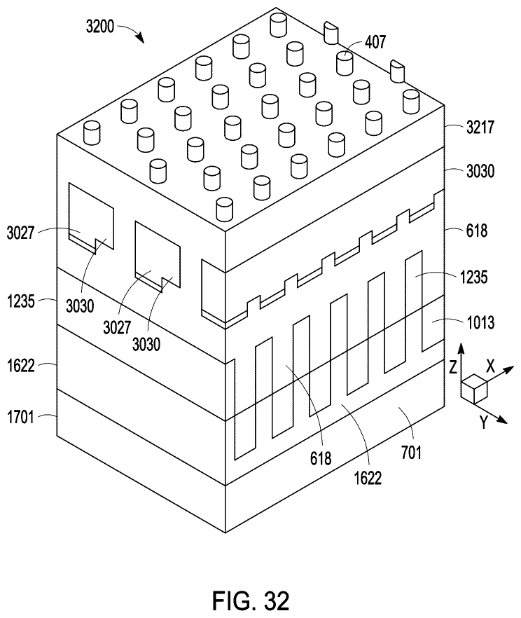

FIG. 32 shows a structure 3200 after processing structure 3000 of FIG. 30. Dielectric 3217 has been formed as a partial fill, followed by performing a wet recess. Dielectric 3217 can be, but is not limited to, oxygen. The junctions of the cell contacts of pillars 407 have been implanted for coupling to capacitors. The implants can be n+ implants.

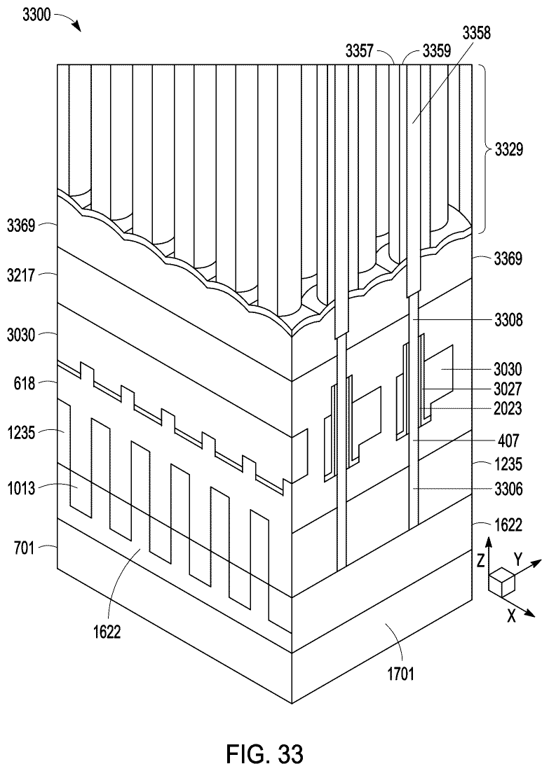

FIG. 33 shows a structure 3300 after processing structure 3200 of FIG. 32. An etch stop 3369 has been formed. Etch stop 3369 can be formed by a deposition procedure appropriate for the material used for the etch stop 3369. Etch stop 3369 can be a nitride etch stop. A set of capacitors have been formed on etch stop 3369. In forming the capacitors, bottom electrodes 3358 have been formed coupled to pillars 407. Top electrodes 3357 have been formed, separated from bottom electrodes 3358 by capacitor dielectrics 3359. Capacitor dielectrics 3359 can be formed as, but are not limited to, high-k dielectrics. The capacitor process can be implemented using the same mask-set that was used to pattern the active areas of the GAA transistors. The capacitor module can be aligned on the junction of the cell contact-active area-channel arrangement provided by pillars 407.

FIG. 34 shows a structure 3400 after processing structure 3300 of FIG. 33. A cover layer 3498 has been formed on the top of the set of capacitors. Structure 3400 provides an array structure that is ready to be processed with control and sensing circuitry of a memory device such as a DRAM device. Cover layer 3498 can be a wafer used to mount structure 3400 for coupling to the control and sensing circuitry.

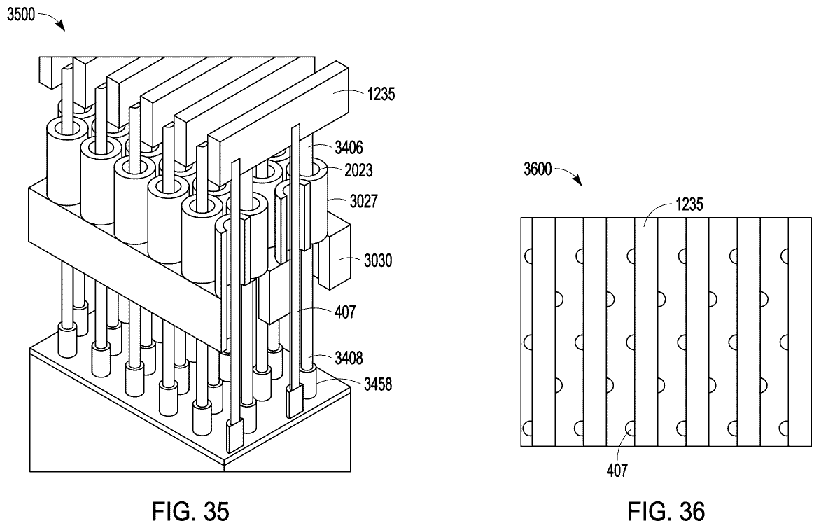

FIGS. 35-37 shows details of structure 3400 of FIG. 34. Structure 3400 has been flipped and the capacitors on top in FIG. 34 are now at the bottom in the orientation shown in FIGS. 35-37. To provide a more detailed view of structure 3400, various dielectric layers formed in the fabrication of structure 3400 are not shown in structure 3500 of FIG. 35. Metal 1235 of BLs are wrapped around junction cell contacts of active areas 3306 of GAA transistors having channel formed by pillars 407. Formed around pillars 407 are gates 3027 of the GAA transistors separated by dielectric material 2023, where gates 3027 contact WLs. Pillars 407 include junction bitcon contacts of active areas 3308 of the GAA transistors contacting electrodes 3358 of capacitors of the memory cells of structure 3300.

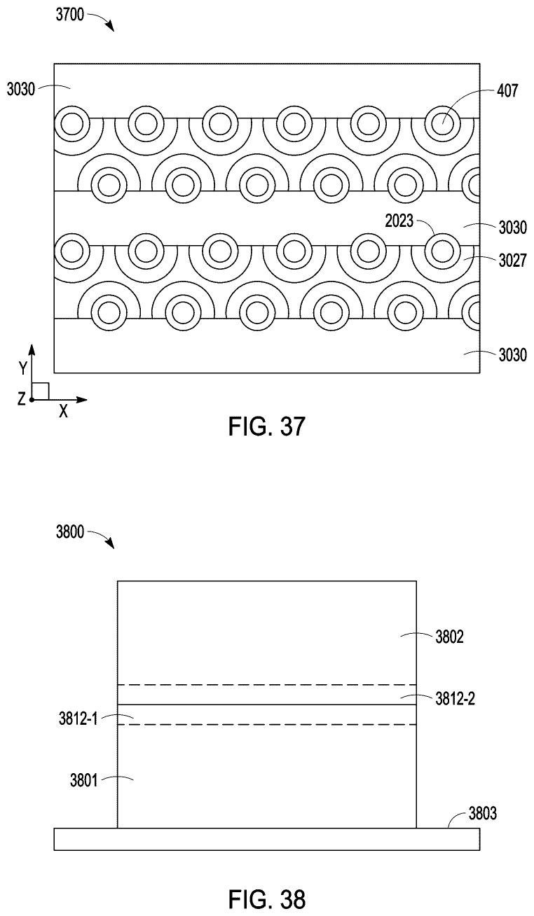

FIG. 37 shows a representation 3700 of a top view of structure 3500 with respect to metal 1235 of BLs. Metal 1235 of structure 3400 and structure 3500 can be referred to as BLs 1235. BLs 1235 are separated from each other, with each BL 1235 contacting multiple memory cells by contacting multiple pillars 407. FIG. 37 shows a representation 3700 of a top view of structure 3500 with respect to WLs 3030. WLs 3030 contact multiple memory cells by contacting gate 3027 of the GAA transistor of each memory cell, where memory cells of the multiple memory cells are on each side of an WL 3030. WLs 3030 contact gates 3027 of the GAA transistors arranged as access devices to capacitors 3329 of structure 3400.

The process flow of FIGS. 3-37 provides a number of enhancements to memory devices such as DRAM devices. In this process flow or similar process flow, BLs can be formed before forming WLs. WLs can be formed as replacement gates of GAA transistors, which can provide enhanced gate control. The capacitor formation of this process flows allows the use of redistribution layers (RDLs) to be skipped. A typical DRAM uses RDL interconnect to rotate cell contact to a hexagonal form for a capacitor to land on. A capacitor is preferred in hexagonal form, because it has the highest surface area (hence the storage capacity) when it is hexagonal. Having a hexagonal active area, removes the need for patterning a hexagonal RDL module. Avoidance of the use of a number of RDLs can provide cost reduction in fabrication of a memory device.

Various deposition techniques for components in the process flows discussed herein can be used that are typical for the material being formed, the dimensions of the material being formed, and the architecture in which the material is being formed in the fabrication of the memory device. Material and structures can be formed by a suitable process such as, but not limited to, a deposition process, where the deposition process can include, but is not limited to, physical vapor deposition (PVD), CVD, ALD, or other deposition process. Other processes can be used. Selective etching can be used to remove selected regions in the processing discussed with respect to the process flows. Selective etching is a process in which one or more materials are removed from a structure, while one or more other materials remain in the structure with no or little removal. Selective etching can depend on the material to be etched, the material not to be etched, the etchant employed, and the method for etching. Types of etching include wet etching and dry etching, where each of these two basic methods include a number of different etching procedures. In addition, conventional masking techniques, providing protective regions in the processing, can be used in removal of selected regions in forming the components of the memory device.

FIG. 38 illustrates an embodiment of an example architecture 3800 in which structure 3400 of FIG. 34 or similar structure can be located. Architecture 3800 is structured as a wafer-to-wafer interconnect architecture, which includes a control wafer 3802 having a bonding region 3812-2 attached to an array wafer 3801 having a bonding region 3812-1. The combination of control wafer 3802 attached to array wafer 3801 can be mounted on a carrier wafer 3803 or other appropriate platform. Control wafer 3802 can be attached to array wafer 3801 by conducting a bonding of bonding region 3812-1 to bonding region 3812-2. The bonding process can be conducted through fusion bonding. Array wafer 3801 can include one or more of structure 3400 or similar structures having one or more arrays of memory cells. Control wafer 3802 can include control and sensing circuitry for operation of arrays of memory cells of the one or more structures 3400 of array wafer 3801 in a CoA architecture. Alternatively, the vertical order on carrier wafer 3803 of control wafer 3802 attached to array wafer 3801 can be reversed, configuring architecture 3800 as a CuA architecture.

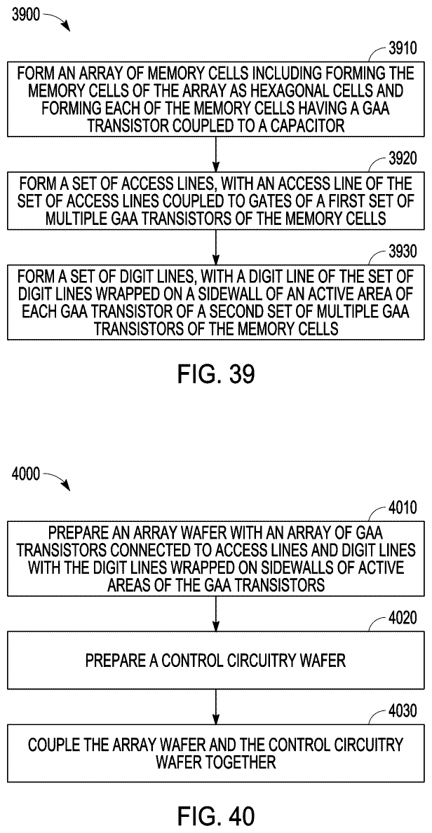

FIG. 39 is a flow diagram of features of an embodiment of an example method 3900 of forming a memory device. At 3910, an array of memory cells is formed. The memory cells are formed as hexagonal cells and each of the memory cells is formed having a gate-all-around (GAA) transistor coupled to a capacitor. The capacitor can be formed in a hexagonal arrangement.

At 3920, a set of WLs is formed. An WL of the set of WLs is coupled to gates of a first set of multiple GAA transistors of the memory cells. The other WLs of the set and other WLs can also be coupled to gates of other sets of other multiple GAA transistors.

At 3930, a set of BLs is formed. A BL of the set of BLs is wrapped on a sidewall of an active area of each GAA transistor of a second set of multiple GAA transistors of the memory cells. The other BLs of the set and other BLs can also be wrapped on sidewalls of active areas of each GAA transistor of other sets of multiple GAA transistors of the memory cells. The set of WLs can be located at 90° angled relative to the set of BLs. The BLs can be formed before forming the WLs.

Variations of method 3900 or methods similar to method 3900 can include a number of different embodiments that may be combined depending on the application of such methods and/or the architecture of systems including a memory device for which such methods are implemented. Such methods can include forming control logic and sensing circuitry above the array. The control logic and sensing circuitry can be formed above the array in a wafer and combined with an array wafer, in which the array is formed, in a wafer-to-wafer interconnect architecture. Wafer-to-wafer interconnect architectures can include a wafer-on-wafer architecture.

Variations of method 3900 or methods similar to method 3900 can include forming vertical nanowires extending above a substrate, with the vertical nanowires having channel structures around which gates of the GAA transistors are formed. The vertical nanowires can include epitaxial silicon on silicon germanium above a silicon substrate.

Variations of method 3900 or methods similar to method 3900 can include conducting a first number of fabrication procedures. Vertical semiconductor pillars can be formed for the GAA transistors, where the vertical semiconductor pillars extend above a substrate. A dielectric can be formed between the vertical semiconductor pillars. A damascene structure on the dielectric can be patterned. Sidewalls of the vertical semiconductor pillars in the dielectric can be exposed, using the patterned damascene structure, and can be doped. Metal can be formed for the BLs of the set of BLs, where the metal is wrapped on the doped sidewalls.

Variations of method 3900 or methods similar to method 3900 can include conducting a second number of fabrication procedures. Vertical semiconductor pillars can be formed extending above a substrate. Active areas can be formed in the vertical semiconductor pillars. Metal, for the BLs of the set, can be formed wrapped on the sidewalls of the active areas. Gates of the GAA transistors can be formed surrounding the vertical semiconductor pillars, where the gates are formed above a level at which the metal was formed. The capacitors can be formed coupled to the vertical semiconductor pillars after forming the GAA transistors. Variations can include forming the GAA transistors with gate oxides between gates of the GAA transistors and channels of the GAA transistors by depositing the gate oxides on vertical semiconductor pillars or forming the gate oxides by in-situ steam generation on the vertical semiconductor pillars.

FIG. 40 is a flow diagram of features of an embodiment of an example method of forming a memory device. At 4010, an array wafer is prepared with an array of GAA transistors connected to WLs and BLs, with the BLs wrapped on sidewalls of active areas of the GAA transistors. At 4020, a control circuitry wafer is prepared. Preparation of the control circuitry wafer can include forming SAs or SWDs for the memory array.

At 4030, the array wafer and the control circuitry wafer are coupled together. The coupling of the array wafer and the control circuitry wafer can be realized by bonding the array wafer and the control circuitry wafer together. Contacts connecting one or more memory arrays on the array wafer to circuits on the control circuitry wafer can be patterned. For example, the patterned contacts can include, but is not limited to, one or more SAs on the control circuitry wafer to BLs on the array wafer or SWDs on the control circuitry wafer to WLs on the array wafer. The control circuitry can be coupled above the array wafer.

Variations of method 4000 or methods similar to method 4000 can include a number of different embodiments that may be combined depending on the application of such methods and/or the architecture of systems including a memory device for which such methods are implemented. Such methods can include forming the GAA transistors as thin film transistors. Variations can include coupling the array wafer and the control circuitry wafer together by bonding the control circuitry wafer above the array wafer. Variations can include forming the BLs using a damascene process. Variations can include forming the array of GAA transistors as hexagonal memory cells in a 4F² architecture. The array of GAA transistors as hexagonal memory cells in a 4F² open BL architecture.

Variations of method 4000 or methods similar to method 4000 can include conducting a number of fabrication procedures for preparing the array wafer. Semiconductor pillars can be formed above a substrate. BLs can be formed wrapped around doped portions of the semiconductor pillars, where the doped portions of the semiconductor pillars provide active areas of the GAA transistors. A bonding layer can be formed above the BLs and attached to a carrier wafer. The carrier wafer with the bonding layer can be flipped after attaching the bonding layer. Formation of the GAA transistors can be completed after flipping the carrier wafer and the GAA transistors can be coupled to capacitors.

In various embodiments, a memory device can comprise an array of memory cells, with each of the memory cells having a GAA transistor arranged as hexagonal vertical channel transistor coupled to a capacitor. The capacitor can be in a hexagonal arrangement. An WL is coupled to gates of a first set of multiple GAA transistors of the memory cells. The other WLs of the first set and other WLs can also be coupled to gates of other sets of other multiple GAA transistors. A BL is coupled to a second set of multiple GAA transistors of the memory cells, where the BL is wrapped on a sidewall of an active area of each GAA transistor of the second set. The other BLs of the second set and other BLs can also be wrapped on sidewalls of active areas of each GAA transistor of other sets of multiple GAA transistors of the memory cells.

Variations of such a memory device and its features, as taught herein, can include a number of different embodiments and features that can be combined depending on the application of such memory devices, the format of such memory devices, and/or the architecture in which such memory devices are implemented. Variations of such memory devices can include the memory device having control logic and sensing circuitry above the array. The control logic and sensing circuitry and the array of memory cells can be arranged in a wafer-to-wafer interconnect architecture.

Variations of such a memory device and its features can include the array of memory cells having a 4F² cell configuration. Variations can include a channel structure and active areas of the GAA transistor of a memory cell being structured in a vertical nanowire. The vertical nanowire can include epitaxial silicon on silicon germanium.

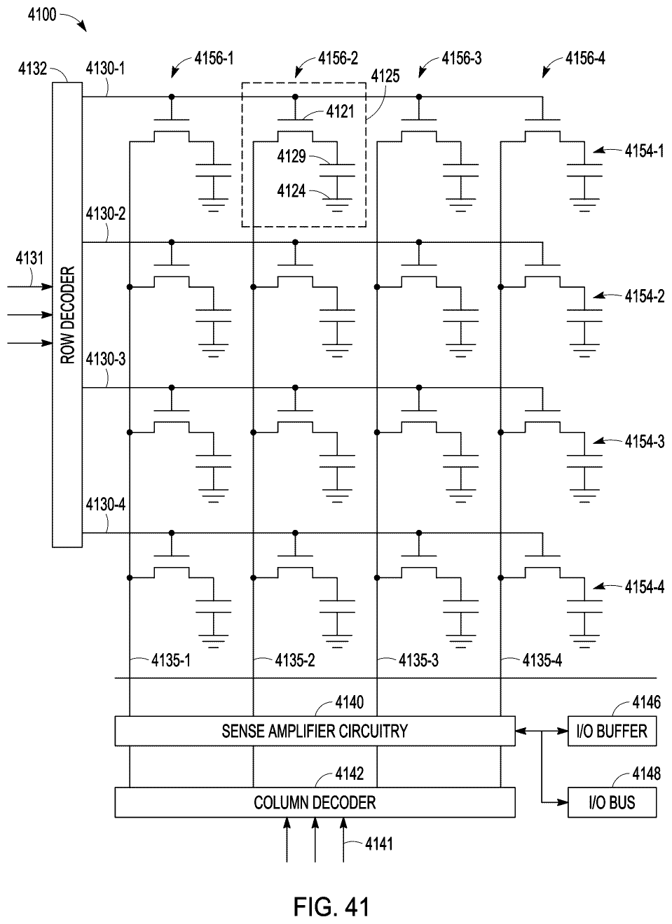

FIG. 41 is a schematic of an electrical arrangement of components of an embodiment of an example DRAM device 4100 that can include a physical architecture having an array of memory cells arranged as hexagonal cells, with each of the memory cells having a GAA transistor coupled to a capacitor. The memory cells can be coupled to BLs, where each of the BLs is wrapped on a sidewall of an active area of the GAA transistor of each memory cell to which the BL is coupled. Each WL can be structured contacting gates of GAA transistors of memory cells to which the given WL is coupled. The array of memory cells can be structured in an arrangement associated herein with respect to FIGS. 1-40. DRAM device 4100 can include an array of memory cells 4125 (only one being labeled in FIG. 41 for ease of presentation) arranged in rows 4154-1, 4154-2, 4154-3, and 4154-4 and columns 4156-1, 4156-2, 4156-3, and 4156-4. The physical orientation of the rows and columns is not shown. Further, while only four rows 4154-1, 4154-2, 4154-3, and 4154-4 and four columns 4156-1, 4156-2, 4156-3, and 4156-4 of four memory cells are illustrated, DRAM devices, like DRAM device 4100, can have significantly more memory cells 4125 (for example, tens, hundreds, or thousands of memory cells) per row or per column.

In this example, each memory cell 4125 can include a single transistor 4121 and a single capacitor 4129, which is commonly referred to as a 1T1C (one-transistor-one capacitor cell). One plate of capacitor 4129, which can be termed the “node plate,” is connected to the drain terminal of transistor 4121, whereas the other plate of the capacitor 4129 is connected to ground 4124 or other reference node. Each capacitor 4129 within the array of 1T1C memory cells 4125 typically serves to store one bit of data, and the respective transistor 4121 serves as an access device to write to or read from storage capacitor 4129. Each transistor 4121 can be realized by a GAA nanowire transistor, as discussed with respect to FIGS. 1-40.

The transistor gate terminals within each row of rows 4154-1, 4154-2, 4154-3, and 4154-4 are portions of respective WLs 4130-1, 4130-2, 4130-3, and 4130-4, and the transistor source terminals within each of columns 4156-1, 4156-2, 4156-3, and 4156-4 are electrically connected to respective BLs 4135-1, 4135-2, 4135-3, and 4135-4. A row decoder 4132 can selectively drive the individual WLs 4130-1, 4130-2, 4130-3, and 4130-4, responsive to row address signals 4131 input to row decoder 4132. Driving a given WL at a high voltage causes the access transistors within the respective row to conduct, thereby connecting the storage capacitors within the row to the respective BLs, such that charge can be transferred between the BLs and the storage capacitors for read or write operations. Both read and write operations can be performed via SA circuitry 4140, which can transfer bit values between memory cells 4125 of the selected row of the rows 4154-1, 4154-2, 4154-3, and 4154-4 and input/output buffers 4146 (for write/read operations) or external input/output data buses 4148.

A column decoder 4142 responsive to column address signals 4141 can select which of the memory cells 4125 within the selected row is read out or written to. Alternatively, for read operations, the storage capacitors 4129 within the selected row can be read out simultaneously and latched, and the column decoder 4142 can then select which latch bits to connect to the output data bus 4148. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DRAM device 4100 can be implemented as an IC within a package that includes pins for receiving supply voltages (for example, to provide the source and gate voltages for the transistors 4121) and signals (including data, address, and control signals). FIG. 41 depicts DRAM device 4100 in simplified form to illustrate basic structural components, omitting many details of the memory cells 4125 and associated WLs 4130-1, 4130-2, 4130-3, and 4130-4 and BLs 4135-1, 4135-2, 4135-3, and 4135-4 as well as the peripheral circuitry. For example, in addition to the row decoder 4132, column decoder 4142, SA circuitry 4140, and buffers 4146, DRAM device 4100 can include further peripheral circuitry, such as a memory control unit that controls the memory operations based on control signals (provided, for example, by an external processor), additional input/output circuitry, or other features associated with a memory device. Details of such peripheral circuitry are generally known to those of ordinary skill in the art and not further discussed herein. The peripheral circuitry can be located above the array of memory cells 4125 in a CoA architecture using a wafer-to-wafer interconnect architecture. Alternatively, the peripheral circuitry can be located under the array of memory cells 4125 in a CuA architecture. Alternatively, the peripheral circuitry can be located in a region of the IC of the memory device adjacent an array region having the array of memory cells 4125.

In two-dimensional (2D) DRAM arrays, the rows 4154-1, 4154-2, 4154-3, and 4154-4 and columns 4156-1, 4156-2, 4156-3, and 4156-4 of memory cells 4125 can be arranged along a single horizontal plane (i.e., a plane parallel to the layers) of the semiconductor substrate, for example, in a rectangular lattice with WLs 4130-1, 4130-2, 4130-3, and 4130-4 and BLs 4135-1, 4135-2, 4135-3, and 4135-4. In 3D DRAM arrays, the memory cells 4125 can be arranged in a 3D lattice with a set of memory cells and associated WLs and BLs at a level above another set of memory cells and their associated WLs and BLs.

Memory devices having identical or similar features to example DRAM device 4100 and the structures associated with FIGS. 1-40 can be implemented in a variety of electronic devices. Electronic devices, such as mobile electronic devices (for example, smart phones, tablets, and other similar communication-related devices), electronic devices for use in automotive applications (for example, automotive sensors, control units, driver-assistance systems, passenger safety systems, comfort systems, or other similar systems), and internet-connected appliances or devices (for example, internet-of-things (IoT) devices, or other network-related devices), have varying storage needs depending on, among other things, the type of electronic device, use environment, performance expectations, or other criteria.

Such electronic devices can be broken down into several main components: a processor (for example, a central processing unit (CPU) or other main processor); memory (for example, one or more volatile or nonvolatile RAM memory device, such as DRAM, mobile or low-power double-data-rate synchronous DRAM (DDR SDRAM), or other similar memory devices); and a storage device (for example, non-volatile memory (NVM) device, such as flash memory, ROM, a solid-state drive (SSD), a MultiMediaCard (MMC), other memory card structure or assembly, or other similar storage devices). In certain examples, electronic devices can include a user interface (for example, a display, touch-screen, keyboard, one or more buttons, or other similar interfacing structure), a graphics processing unit (GPU), a power management circuit, a baseband processor, one or more transceiver circuits, or other similar device. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

The following examples are example embodiments of devices and methods, in accordance with the teachings herein.

An example memory device 1 can comprise an array of memory cells, with each of the memory cells having a GAA transistor arranged as hexagonal vertical channel transistor coupled to a capacitor; an WL coupled to gates of a first set of multiple GAA transistors of the memory cells; and a BL coupled to a second set of multiple GAA transistors of the memory cells, the BL wrapped on a sidewall of an active area of each GAA transistor of the second set.

An example memory device 2 can include features of example memory device 1 and can include control logic and sensing circuitry above the array.

An example memory device 3 can include features of example memory device 2 and any of the preceding example memory devices and can include the control logic and sensing circuitry and the array of memory cells being arranged in a wafer-to-wafer interconnect architecture.

An example memory device 4 can include features of any of the preceding example memory devices and can include the array of memory cells having a 4F² cell configuration.

An example memory device 5 can include features of any of the preceding example memory devices and can include a channel structure and active areas of the GAA transistor of a memory cell structured in a vertical nanowire.

An example memory device 6 can include features of example memory device 5 and any of the preceding example memory devices and can include the vertical nanowire to include epitaxial silicon.

In an example memory device 7, any of the memory devices of example memory devices 1 to 6 may include memory devices incorporated into an electronic apparatus further comprising a host processor and a communication bus extending between the host processor and the memory device.

In an example memory device 8, any of the memory devices of example memory devices 1 to 7 may be modified to include any structure presented in another of example memory device 1 to 7.

In an example memory device 9, any apparatus associated with the memory devices of example memory devices 1 to 8 may further include a machine-readable storage device configured to store instructions as a physical state, wherein the instructions may be used to perform one or more operations of the apparatus.

In an example memory device 10, any of the memory devices of example memory devices 1 to 9 may be formed in accordance with any of the below example methods 1 to 13 of forming a memory device or example methods 1 to 9 of forming a memory device.

An example method 1 of forming a memory device can comprise forming an array of memory cells including forming the memory cells of the array as hexagonal cells and forming each of the memory cells having a gate-all-around (GAA) transistor coupled to a capacitor; forming a set of WLs, with an WL of the set of WLs coupled to gates of a first set of multiple GAA transistors of the memory cells; and forming a set of BLs, with a BL of the set of BLs wrapped on a sidewall of an active area of each GAA transistor of a second set of multiple GAA transistors of the memory cells.

An example method 2 of forming a memory device can include features of example method 1 of forming a memory device and can include forming control logic and sensing circuitry above the array.

An example method 3 of forming a memory device can include features of example method 2 of forming a memory device and any of the preceding example methods of forming a memory device and can include forming the control logic and sensing circuitry above the array to include forming the control logic and sensing circuitry in a wafer and combining the wafer with an array wafer, in which the array is formed, in a wafer-to-wafer interconnect architecture.

An example method 4 of forming a memory device can include features of any of the preceding example methods of forming a memory device and can include forming vertical nanowires extending above a substrate, with the vertical nanowires having channel structures around which gates of the GAA transistors are formed.

An example method 5 of forming a memory device can include features of example method 4 of forming a memory device and any of the preceding example methods of forming a memory device and can include forming the vertical nanowires to include forming epitaxial silicon above a silicon substrate.

An example method 6 of forming a memory device can include features of any of the preceding example methods of forming a memory device and can include forming vertical semiconductor pillars for the GAA transistors, the vertical semiconductor pillars extending above a substrate; forming a dielectric between the vertical semiconductor pillars; patterning a damascene structure on the dielectric; exposing sidewalls of the vertical semiconductor pillars in the dielectric, using the patterned damascene structure; doping the sidewalls; and forming metal, for the BLs of the set, wrapped on the doped sidewalls.

An example method 7 of forming a memory device can include features of any of the preceding example methods of forming a memory device and can include forming vertical semiconductor pillars extending above a substrate; forming first active areas in the vertical semiconductor pillars; forming metal, for the BLs of the set, wrapped on the sidewalls of the first active areas; forming gates of the GAA transistors surrounding the vertical semiconductor pillars, the gates formed above a level at which the metal was formed; and forming the capacitors coupled to the vertical semiconductor pillars after forming the GAA transistors.

An example method 8 of forming a memory device can include features of any of the preceding example methods of forming a memory device and can include forming the GAA transistors with gate oxides between gates of the GAA transistors and channels of the GAA transistors by depositing the gate oxides on vertical semiconductor pillars or forming the gate oxides by in-situ steam generation on the vertical semiconductor pillars.

In an example method 9 of forming a memory device, any of the example methods 1 to 8 of forming a memory device may be performed in forming an electronic apparatus further comprising a host processor and a communication bus extending between the host processor and the memory device.

In an example method 10 of forming a memory device, any of the example methods 1 to 9 of forming a memory device may be modified to include operations set forth in any other of example methods 1 to 9 of forming a memory device.

In an example method 11 of forming a memory device, any of the example methods 1 to 10 of forming a memory device may be implemented at least in part through use of instructions stored as a physical state in one or more machine-readable storage devices.

An example method 12 of forming a memory device can include features of any of the preceding example methods 1 to 11 of forming a memory device and can include forming features associated with any features of example memory devices 1 to 10.

An example method 13 of forming a memory device can comprise preparing an array wafer with an array of gate-all-around (GAA) transistors connected to WLs and BLs, with the BLs wrapped on sidewalls of active areas of the GAA transistors; preparing a control circuitry wafer; and coupling the array wafer and the control circuitry wafer together.

An example method 14 of forming a memory device can include features of example method 13 of forming a memory device and can include forming the GAA transistors as thin film transistors.

An example method 15 of forming a memory device can include features of any of the preceding example methods 13-14 of forming a memory device and can include preparing the array wafer to include: forming semiconductor pillars above a substrate; forming BLs wrapped around doped portions of the semiconductor pillars, the doped portions of the semiconductor pillars providing active areas of the GAA transistors; forming a bonding layer above the BLs; attaching the bonding layer to a carrier wafer; flipping the carrier wafer with the bonding layer, after attaching the bonding layer; completing formation of the GAA transistors after flipping the carrier wafer; and coupling the GAA transistors to capacitors.

An example method 16 of forming a memory device can include features of any of the preceding example methods 13-15 of forming a memory device and can include coupling the array wafer and the control circuitry wafer together to include bonding the control circuitry wafer above the array wafer.

An example method 17 of forming a memory device can include features of any of the preceding example methods 13-16 of forming a memory device and can include forming the BLs using a damascene process.

An example method 18 of forming a memory device can include features of any of the preceding example methods 13-17 of forming a memory device and can include forming the array of GAA transistors as hexagonal memory cells in a 4F² architecture.

In an example method 19 of forming a memory device, any of the example methods 13 to 18 of forming a memory device may be performed in forming an electronic apparatus further comprising a host processor and a communication bus extending between the host processor and the memory device.

In an example method 20 of forming a memory device, any of the example methods 13 to 19 of forming a memory device may be modified to include operations set forth in any other of example methods 13 to 19 of forming a memory device.

In an example method 21 of forming a memory device, any of the example methods 13 to 20 of forming a memory device may be implemented at least in part through use of instructions stored as a physical state in one or more machine-readable storage devices.

An example method 22 of forming a memory device can include features of any of the preceding example methods 13 to 21 of forming a memory device and can include forming features associated with any features of example memory devices 1 to 10.

An example machine-readable storage device storing instructions, that when executed by one or more processors, cause a machine to perform operations, can comprise instructions to perform functions associated with any features of example memory devices 1 to 10 or perform methods associated with any features of example methods 1 to 22 of forming a memory device.

Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
an array of memory cells, with each of the memory cells having a gate-all-around (GAA) transistor arranged as hexagonal vertical channel transistor coupled to a capacitor;
an access line coupled to gates of a first set of multiple GAA transistors of the memory cells; and
a digit line coupled to a second set of multiple GAA transistors of the memory cells, the digit line wrapped on a sidewall of an active area of each GAA transistor of the second set.

2. The memory device of claim 1, wherein the memory device includes control logic and sensing circuitry above the array.

3. The memory device of claim 2, wherein the control logic and sensing circuitry and the array of memory cells are arranged in a wafer-to-wafer interconnect architecture.

4. The memory device of claim 1, wherein the array of memory cells has a 4F² cell configuration.

5. The memory device of claim 1, wherein a channel structure and active areas of the GAA transistor of a memory cell are structured in a vertical nanowire.

6. The memory device of claim 5, wherein the vertical nanowire includes epitaxial silicon.

7. A method of forming a memory device, the method comprising:
forming an array of memory cells including forming the memory cells of the array as hexagonal cells and forming each of the memory cells having a gate-all-around (GAA) transistor coupled to a capacitor;
forming a set of access lines, with an access line of the set of access lines coupled to gates of a first set of multiple GAA transistors of the memory cells; and
forming a set of digit lines, with a digit line of the set of digit lines wrapped on a sidewall of an active area of each GAA transistor of a second set of multiple GAA transistors of the memory cells.

8. The method of claim 7, wherein the method includes forming control logic and sensing circuitry above the array.

9. The method of claim 8, wherein forming the control logic and sensing circuitry above the array includes forming the control logic and sensing circuitry in a wafer and combining the wafer with an array wafer, in which the array is formed, in a wafer-to-wafer interconnect architecture.

10. The method of claim 7, wherein the method includes forming vertical nanowires extending above a substrate, with the vertical nanowires having channel structures around which gates of the GAA transistors are formed.

11. The method of claim 10, wherein forming vertical nanowires includes forming epitaxial silicon on silicon germanium above a silicon substrate.

12. The method of claim 7, wherein the method includes:
forming vertical semiconductor pillars for the GAA transistors, the vertical semiconductor pillars extending above a substrate;
forming a dielectric between the vertical semiconductor pillars;
patterning a damascene structure on the dielectric;
exposing sidewalls of the vertical semiconductor pillars in the dielectric, using the patterned damascene structure;
doping the sidewalls; and
forming metal, for the digit lines of the set, wrapped on the doped sidewalls.

13. The method of claim 7, wherein the method includes:
forming vertical semiconductor pillars extending above a substrate;
forming first active areas in the vertical semiconductor pillars;
forming metal, for the digit lines of the set, wrapped on the sidewalls of the first active areas;
forming gates of the GAA transistors surrounding the vertical semiconductor pillars, the gates formed above a level at which the metal was formed; and
forming the capacitors coupled to the vertical semiconductor pillars after forming the GAA transistors.

14. The method of claim 7, wherein the method includes forming the GAA transistors with gate oxides between gates of the GAA transistors and channels of the GAA transistors by depositing the gate oxides on vertical semiconductor pillars or forming the gate oxides by in-situ steam generation on the vertical semiconductor pillars.

15. A method of forming a memory device, the method comprising:
preparing an array wafer with an array of gate-all-around (GAA) transistors connected to access lines and digit lines, with the digit lines wrapped on sidewalls of active areas of the GAA transistors;
preparing a control circuitry wafer; and
coupling the array wafer and the control circuitry wafer together.

16. The method of claim 15, wherein the method includes forming the GAA transistors as thin film transistors.

17. The method of claim 15, wherein preparing the array wafer includes:
forming semiconductor pillars above a substrate;
forming digit lines wrapped around doped portions of the semiconductor pillars, the doped portions of the semiconductor pillars providing active areas of the GAA transistors;
forming a bonding layer above the digit lines;
attaching the bonding layer to a carrier wafer;
flipping the carrier wafer with the bonding layer, after attaching the bonding layer;
completing formation of the GAA transistors after flipping the carrier wafer; and
coupling the GAA transistors to capacitors.

18. The method of claim 15, wherein coupling the array wafer and the control circuitry wafer together includes bonding the control circuitry wafer above the array wafer.

19. The method of claim 15, wherein the method includes forming the digit lines using a damascene process.

20. The method of claim 15, wherein the method includes forming the array of GAA transistors as hexagonal memory cells in a 4F² architecture.
